(19) United States
(12) Patent Application Publication
(10) Pub. No.: US 2021/0097900 A1
(43) Pub. Date: Apr. 1, 2021

(54) DISPLAY PANEL AND DISPLAY DEVICE

(71) Applicant: Wuhan China Star Optoelectronics Semiconductor Display Technology Co., Ltd., Wuhan, Hubei (CN)

(72) Inventor: Lei CUI, Shenzhen, Guangdong (CN)

(21) Appl. No.: 16/079,343

(22) PCT Filed: Oct. 18, 2017
(86) PCT No.: PCT/CN2017/106649

§ 371 Date: Aug. 23, 2018

(30) Foreign Application Priority Data
Sep. 4, 2017 (CN) 201710786098.1

(51) Int. Cl. G09F 9/30; G06F 3/041; H05K 1/18

(52) U.S. Cl. CPC G09F 9/301; H05K 2201/10128; H05K 1/189; G06F 3/0412

(57) ABSTRACT

The present disclosure relates to a display panel, including: an array substrate, a light-emitting layer, a touch panel, a first flexible circuit board, and a second flexible circuit board. The array substrate includes a display region and an edge-bonding region configured on an edge of the display region. The light-emitting layer is stacked on the display region. The first flexible circuit board joins to the edge-bonding region. The touch panel is stacked on one side of the light-emitting layer facing away the array substrate. The second flexible circuit board is flexibly connected between the touch panel and the edge-bonding region. The edge-bonding region includes a first conductive lead. The second flexible circuit board connects to the first flexible circuit board via the first conductive lead. As such, the internal configuration and the small-sized design of the display device may be facilitated, and may improve user experience.

### CROSS-REFERENCE TO RELATED APPLICATION

This application claims the priority of Chinese Patent Application No. 201710786098.1, entitled “DISPLAY PANEL AND DISPLAY DEVICE”, filed on Sep. 4, 2017, the disclosure of which is incorporated herein by reference in its entirety.

### FIELD OF THE INVENTION

The present disclosure relates to a display field, and more particularly to a display panel and a display device.

### BACKGROUND OF THE INVENTION

With the development of the technology, display technology has continued to be innovated. Display devices, such as active-matrix organic light emitting diodes (AMOLED), have been widely adopted. The display devices having the touch function have become a part of human's daily life. Currently, the display screen carried with an external touch panel is the most common way to integrate touch function into the display device.

Conventionally, the touch panel is bonded on the surface of the display panel. The flexible printed circuit (FPC) drawn from the edge of the touch panel is connected to a flexible circuit board drawn from the edge of the array substrate by a connector, so as to electrically connect the touch panel and the array substrate to the mainboard. Due to the thickness of the connector, the overall thickness of the display device is increased. The connector cannot be bent, and the overlapping portion of the two flexible circuit boards and the connectors may affect the bending of the flexible circuit board, which may affect the internal configuration and the small-sized design of the display device.

### SUMMARY OF THE INVENTION

The present disclosure relates to a display panel and a display device to solve the problems, i.e., the overall thickness of the display device may be increased due to the thickness of the connector and the connectors may affect the bending of the flexible circuit board. These may affect the internal configuration and the small-sized design of the display device.

In one aspect, the present disclosure relates to a display panel, including: an array substrate, a light-emitting layer, a touch panel, a first flexible circuit board, and a second flexible circuit board; wherein the array substrate includes a display region and an edge-bonding region configured on an edge of the display region, the light-emitting layer is stacked on the display region, and the first flexible circuit board joins to the edge-bonding region; the touch panel is stacked on one side of the light-emitting layer facing away the array substrate, the second flexible circuit board is flexibly connected between the touch panel and the edge-bonding region, and the edge-bonding region includes a first conductive lead, and the second flexible circuit board connects to the first flexible circuit board via the first conductive lead.

The display panel further includes a touch chip disposed on the first flexible circuit board, and the touch chip electrically connects to the touch panel via the first flexible circuit board and the second flexible circuit board.

The first flexible circuit board includes a fixing end and a carrying portion integrally connected with each other, the fixing end joins to the edge-bonding region, the carrying portion is configured outside of the array substrate, and the carrying portion is configured to carry the touch chip.

The display panel further includes a display driving chip configured on the edge-bonding region, and a vertical projection of the second flexible circuit board with respect to the array substrate covers the display driving chip.

A bonding region of the second flexible circuit board is formed between a connecting portion of the second flexible circuit board and the edge-bonding area, and a connecting portion between the display driving chip and the edge-bonding region, and the bonding region of the second flexible circuit board are interleaved with each other.

The display panel further includes a cover stacked on one side of the touch panel facing away the light-emitting layer; a touch area is formed on a vertical projection area of the cover with respect to the touch panel; one side of the touch area is configured with an edge region, and the second flexible circuit board joins to the edge region.

The edge-bonding region further includes a second conductive lead, the display driving chip electrically connect to the first flexible circuit board via the second conductive lead, and the first conductive lead and the second conductive lead are interleaved with each other.

The display panel further includes an optical clear adhesive (OCA) layer, and the touch panel is fixed on the light-emitting layer via the OCA layer.

The first flexible circuit board and the second flexible circuit board are bonded on the edge-bonding region via an anisotropic conductive film (ACF).

In another aspect, the present disclosure further relates to a display device including a mainboard and a display panel; wherein the display panel includes: an array substrate, a light-emitting layer, a touch panel, a first flexible circuit board; and a second flexible circuit board; wherein the array substrate includes a display region and an edge-bonding region configured on an edge of the display region, the light-emitting layer is stacked on the display region, and the first flexible circuit board joins to the edge-bonding region; the touch panel is stacked on one side of the array substrate facing away the light-emitting layer, the second flexible circuit board is flexibly connected between the touch panel and the edge-bonding region, and the edge-bonding region includes a first conductive lead, and the second flexible circuit board connects to the first flexible circuit board via the first conductive lead; the display panel electrically connects to the mainboard via the first flexible circuit board.

The display panel further includes a touch chip disposed on the first flexible circuit board, and the touch chip electrically connects to the touch panel via the first flexible circuit board and the second flexible circuit board.

The first flexible circuit board includes a fixing end and a carrying portion integrally connected with each other, the fixing end joins to the edge-bonding region, the carrying portion is configured outside of the array substrate, and the carrying portion is configured to carry the touch chip.

The display panel further includes a display driving chip configured on the edge-bonding region, and a vertical projection of the second flexible circuit board with respect to the array substrate covers the display driving chip.

A bonding region of the second flexible circuit board is formed between a connecting portion of the second flexible circuit board and the edge-bonding area, and a connecting portion between the display driving chip and the edge-bonding region, and the bonding region of the second flexible circuit board are interleaved with each other.

The display panel further includes a cover stacked on one side of the touch panel facing away the light-emitting layer; a touch area is formed on a vertical projection area of the cover with respect to the touch panel, one side of the touch area is configured with an edge region, and the second flexible circuit board joins to the edge region.

The edge-bonding region further includes a second conductive lead, the display driving chip electrically connect to the first flexible circuit board via the second conductive lead, and the first conductive lead and the second conductive lead are interleaved with each other.

The display panel further includes an OCA layer, and the touch panel is fixed on the light-emitting layer via the OCA layer.

The first flexible circuit board and the second flexible circuit board are bonded on the edge-bonding region via an ACF.

In view of the above, the second flexible circuit board electrically connects to the first flexible circuit board via the first conductive lead of the edge-bonding region. As such, the touch panel may connect to the mainboard via the first circuit board. The first flexible circuit board may connect to the second flexible circuit board without the connector, and the overall thickness of the display device may not be increased. There is no overlapping portion between the first flexible circuit board and the second flexible circuit board, and the bending of the first flexible circuit board may not be affected by the second flexible circuit board and the components, such as the connectors, which may facilitate to the internal configuration and the small-sized design of the display device, and may improve user experience.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a side view of a display panel in accordance with one embodiment of the present disclosure,

FIG. 2 is a top view of the display panel in accordance with one embodiment of the present disclosure.

FIG. 3 is a partial enlarged view of an array substrate of the display panel in accordance with one embodiment of the present disclosure.

FIG. 4 is a diagram illustrating a connection of the display panel and a mainboard.

FIG. 5 is a schematic view of a display device in accordance with one embodiment of the present disclosure.

### DETAILED DESCRIPTION OF PREFERRED EMBODIMENTS

The following descriptions for the respective embodiments are specific embodiments capable of being implemented for illustrations of the present invention with referring to appended figures.

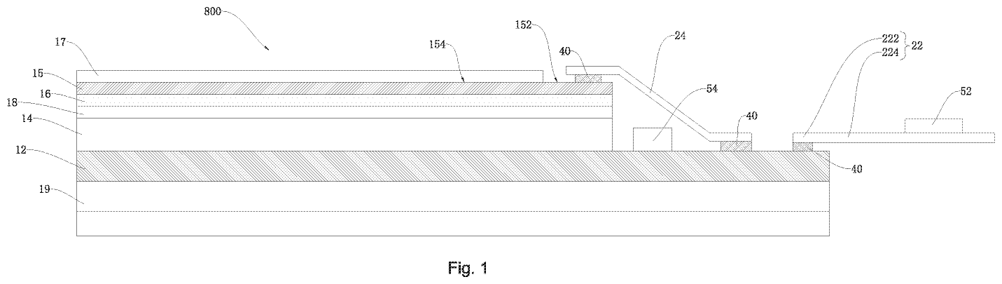

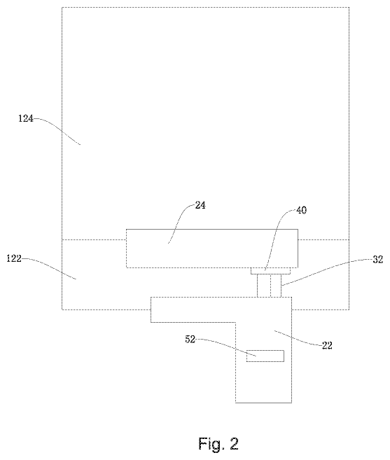

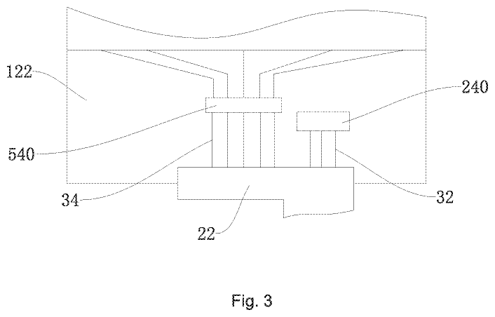

Referring to FIG. 1, FIG. 2, and FIG. 3, the present disclosure relates to a display panel 700 integrated with display function and touch function. Specifically, the display panel 700 includes an array substrate 12, a light-emitting layer 14, and a touch panel 15. The array substrate 12 is configured to control the light-emitting layer 14 to illuminate. The touch panel 15 is externally mounted on the display panel 700. In one example, the light-emitting layer 14 may be an organic light emitting diode (OLED), which has attributes, such as self-illumination, wide viewing angle, almost infinite contrast, low power consumption, high response speed, flexible (bendable), may be used to produce flexible display devices. In one example, the touch panel 15 may be a transparent panel, and images displayed by the light-emitting layer 14 may be displayed through the touch panel 15. In one example, the touch panel 15 may be a capacitive touch panel 15, and the touch panel 15 may achieve the touch function by a configuration of stacking a driving electrode and an induction electrode. The driving electrode and the induction electrode may be patterned indium tin oxide (ITO) thin films, which have attributes, such as great conductivity, high light transmittance, and may have little influence on the images displayed by the light-emitting layer 14. In one example, the array substrate 12 is configured to control light-emitting performance, i.e., to control the displayed images, of the light-emitting layer 14 by controlling each of pixel cells. In one example, the array substrate 12 may include at least one thin film transistor (TFT). Specifically, the TFT may be tow temperature poly-silicon (LTPS) TFT, which has attributes, such as ultra-thin, light weight, and low power consumption. As such, the LTPS TFT, cooperating with the OLEDs, is capable of providing brighter colors and sharper images.

The display panel 700 may further include a first flexible circuit board 22 and a second flexible circuit board 24. The first flexible circuit board 22 and the second flexible circuit board 24 are bendable, and two ends of the first flexible circuit board 22 or two ends of the second flexible circuit board 24 may be electrically connected to electrical components. In one example, the electrical components bonding between the two ends of the first flexible circuit board 22 or the two ends of the second flexible circuit board 24 may be electrically connected to the electrical components connecting to the two ends of the first flexible circuit board 22 or the two ends of the second flexible circuit board 24.

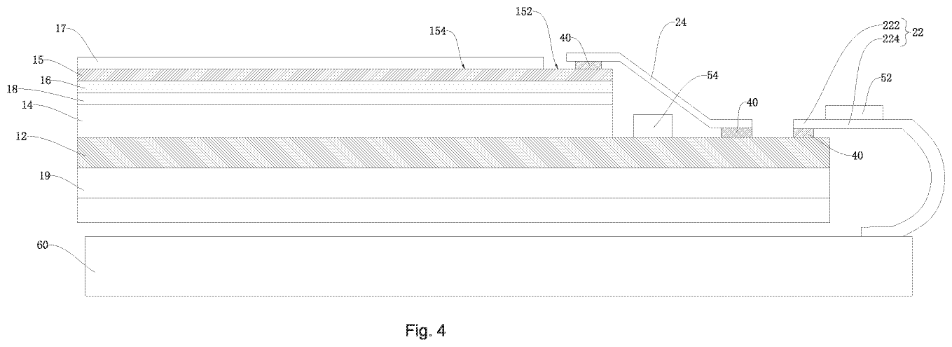

In one example, the array substrate 12 may include a display region 122 and an edge-bonding region 124 configured on an edge of the display region 122. Specifically, the light-emitting layer 14 is stacked on the display region 122. The light-emitting layer 14 covers the display region 122. The array substrate 12 is configured to control the light-emitting layer 14 to display the images, i.e., the display region 122 is configured to display the images. In one example, the edge-bonding region 124 is configured on one side of a longitudinal direction of the array substrate 12. The edge-bonding region 124 is opaque and includes a plurality of patterned conductive leads. Specifically, the conductive leads may be silver glue lines formed by conducting a laser etching process or a chemical etching process on a silver glue layer. In one example, the first flexible circuit board 22 joins to the edge-bonding region 124. Specifically, one side of the first flexible circuit board 22 is bonded to the edge-bonding region 124, the other side of the first flexible circuit board 22 is bonded to a mainboard 60 of the display device to electrically connect the array substrate 12 to the mainboard 60. In another example, the first flexible circuit board 22 may be bent and may connect to the array substrate 12 and the mainboard 60 to save space. Referring to FIG. 4, in one example, the mainboard 60 may be disposed on one side of the array substrate 12 facing away the light-emitting layer 14, and the first flexible circuit board 22 is bent 180 degrees.

In one example, the touch panel 15 is stacked on one side of the light-emitting layer 14 facing away the array substrate 12. The touch panel 15 may be fixed on the light-emitting layer 14 via an optical clear adhesive (OCA) 16. The OCA 16 has high light transmittance, as such loss of light beams of the images displayed by the light-emitting layer 14 may be reduced.

Referring to FIG. 3, the second flexible circuit board 24 is electrically connected between the touch panel 15 and the edge-bonding region 124. The edge-bonding region 124 includes a first conductive lead 32. The second flexible circuit board 24 electrically connects to the first flexible circuit board 22 via the first conductive lead 32. Specifically, one side of the second flexible circuit board 24 bonds to an edge of the touch panel 15, the other side of the second flexible circuit board 22 bonds to the edge-bonding region 124 of the array substrate 12, so as to electrically connect the touch panel 15 to the array substrate 12. In one example, two ends of the second flexible circuit board 24 are configured to connect to the touch panel 15 or the edge-bonding region 124 via an anisotropic conductive film (ACF) 40. The ACF 40 is configured to firmly bond the second flexible circuit board 24 to the edge-bonding region 124 or the touch panel 15, and to electrically connect the second flexible circuit board 24 to the array substrate 12 or the touch panel 15. In one example, the second flexible circuit board 24 electrically connects to the first flexible circuit board 22 via the first conductive lead 32. The first flexible circuit board 22 electrically connects to the mainboard 60, and the touch panel 15 electrically connects to the mainboard 60 via the second flexible circuit board 24, the first conductive lead 32, and the first flexible circuit board 22 in sequence. Specifically, the first conductive lead 32 may be the silver glue line formed by conducting the laser etching process or the chemical etching process on the patterned silver glue layer. The silver glue line has low impedance and is easy to be produced. It is noted that the light-emitting layer 14 and the array substrate 15 configured to achieve the display function may electrically connect to the mainboard 60 via the first flexible circuit board 22, and the touch panel 15 configured to achieve the touch function may also connect to the mainboard 60 via the first flexible circuit board 22. Such that the mainboard 60 may be able to control the display function and the touch function of the display device.

The second flexible circuit board 24 electrically connects to the first flexible circuit board 22 via the first conductive lead 32 of the edge-bonding region 124. As such, the touch panel 15 may connect to the mainboard 60 via the first circuit board 22. The first flexible circuit board 22 may connect to the second flexible circuit board 24 without the connectors, and the overall thickness of the display device may not be increased. There is no overlapping portion between the first flexible circuit board 22 and the second flexible circuit board 24, and the bending of the first flexible circuit board 22 may not be affected by the second flexible circuit board 24 and the components, such as the connectors, which may facilitate to the internal configuration and the small-sized design of the display device, and may improve user experience.

In one example, the display panel 700 may further include a touch chip 52 configured on the first flexible circuit board 22. The touch chip 52 electrically connects to the touch panel 15 via the first flexible circuit board 22 and the second flexible circuit board 24. Specifically, the touch chip 52 is configured to process touch signals transmitted from the touch panel 15 to the touch chip 52. The touch chip 52 is configured on the first flexible circuit board 22, and electrically connects to the first flexible circuit board 22. The touch chip 52 electrically connects to the edge-bonding region 124 of the array substrate 12 via the first flexible circuit board 22, so as to electrically connect to the touch panel 15 via the first conductive lead 32 and the second flexible circuit board 22 in sequence. The touch chip 52 electrically connects to the touch panel 15 to form a complete touch function. The touch chip 52 is configured on the first flexible circuit board 22, and may not affect the bending of the second flexible circuit board 24. As such, a size of the second flexible circuit board 24 may be reduced, the second flexible circuit board 24 may be flexibly bent and connected between the touch panel 15 and the edge-bonding region 124 with a minimum length, and there is no need to consider influence of the touch chip 52 on the size of the second flexible circuit board 24, which may facilitate to the internal configuration and the small-sized design of the display device.

In one example, the first flexible circuit board 22 may include a fixing end 222 and a carrying portion 224 integrally connected with each other. The fixing end 222 joins to the edge-bonding region 124. The carrying portion 224 is configured outside of the array substrate 12. The carrying portion 224 is configured to carry the touch chip 52. In one example, the fixing ends 222 of the first flexible circuit board 22 connects to the edge-bonding region 124 via the ACF 40. The ACF 40 is configured to firmly bond the flexible circuit board 22 and the edge-bonding region 124, and to electrically connect the first flexible circuit bated 22 and the array substrate 12. In one example, the carrying portion 224 may not occupy a space of the edge-bonding region 124, and the touch chip 52 on the carrying portion 224 may not occupy the space of the edge-bonding region 124. Further, the carrying portion 224 is bendable, and the carrying portion 224 may be bent and be bonded to the mainboard 60. The bent carrying portion 224 may occupy less space within the display device, which may facilitate to the space configuration and the small-sized design of the display device. The touch chip 52 may not occupy the space of the edge-bonding region 124, and may not affect a size of the edge-bonding region 124, which facilitate to narrow frame design, and a size of frame of the display device may be reduced. The touch chip 52 may be carried by the bendable carrying portion 224, which facilitates to the internal configuration of the display device, and a size of the display device may be reduced.

In one example, the display panel 700 may further include a display driving chip 54 configured on the edge-bonding region 124. A vertical projection of the second flexible circuit board 24 with respect to the array substrate 12 covers the display driving chip 54. Specifically, the display driving chip 54 electrically connects to the array substrate 12 and the light-emitting layer 14, and the display driving chip 54 is configured to control the images displayed by the display panel 700. The vertical projection of the second flexible circuit board 24 with respect to the array substrate 12 covers the display driving chip 54, i.e., the display driving chip 54 is configured between a horizontal position of a connection point of the second flexible circuit board 24 and the edge-bonding region 124 and a connection point of the second flexible circuit board 24 and the touch panel 15. That is, the display driving chip 54 is configured between a connection point of the second flexible circuit board 24 and the edge-bonding region 124, and an edge of the display region 122. The display chip may not increase the size of the edge-bonding region 124, and the size of the frame of the display device may be reduced, which facilitates the narrow frame design.

In one example, a bonding region 240 of the second flexible circuit board 24 is formed between a connecting portion between the second flexible circuit board 24 and the edge-bonding area 124. A connecting portion between the display driving chip 54 and the edge-bonding region 124, and the bonding region 240 of the second flexible circuit board 24 are interleaved with each other. Specifically, the connecting portion between the display driving chip 54 and the edge-bonding region 124 is configured to be a chip-bonding region 540. The display driving chip 54 may be fixed and electrically connected to the chip-bonding region 540 by welding or the ACF 40. The chip-bonding region 540 and the bonding region 240 of the second flexible circuit board 24 are interleaved with each other, so as to prevent the second flexible circuit board 24 from electrically connecting to the display driving chip 54, and to prevent display signals from interfering by the touch signals, which may affect the display function and the touch function. In one example, the edge-bonding region 124 may further include a second conductive lead 34. The display driving chip 54 may electrically connect to the first flexible circuit board 22 via the second conductive lead 34. The first conductive lead 32 and the second conductive lead 34 are interleaved with each other. In one example, the second conductive lead 34 may be the silver glue line formed by conducting the laser etching process or the chemical etching process on the patterned silver glue layer. The silver glue line has low impedance and is easy to be produced. The first conductive lead 32 is configured to connect the first flexible circuit board 22 and the second flexible circuit board 24, so as to electrically connect the touch panel 15, and the touch chip 52 and the mainboard 60. The second conductive lead 34 is configured to electrically connect the display driving chip 54 and the first flexible circuit board 22, so as to electrically connect the light-emitting layer 14, and the display driving chip 54 and the mainboard 60. The first conductive lead 32 and the second conductive lead 34 are interleaved with each other to prevent the display signals from interfering by the touch signals, which may affect the display function and the touch function.

In one example, the display panel 700 may further include a cover 17 stacked on one side of the touch panel 15 facing away the light-emitting layer 14. A touch area 154 is formed on a vertical projection area of the cover 17 with respect to the touch panel 15, One side of the touch area 154 is configured with an edge region 152, and the second flexible circuit board 24 joins to the edge region 152. Specifically, the cover 17 is configured to protect the touch panel 15, User's fingers may directly touch the cover 17, so as to avoid damages, resulting from directly touching the touch panel 15, causing on the touch panel 15. In one example, the cover 17 may be a polarizer structure configured to filter light beams emitted from the light-emitting layer 14, so as to obtain light beams of the images with an uniform polarization. In one example, the edge region 152 is not covered by the cover 17, and a bonding point is configured on a surface of the edge region 152. One side of the second flexible circuit board 24 may be bonded on the bonding point of the edge region 152, and the second flexible circuit board 24 may be connected between the touch panel 15 and the array substrate 12. In one example, the edge region 152 and the edge-bonding region 124 is configured on the same side of the display panel 700 to reduce a distance between the edge region 152 and the edge-bonding region 124, so as to minimize the size of the second flexible circuit board 24, which may facilitate to the internal configuration and the small-sized design of the display device, and may improve user experience.

The second flexible circuit board 24 electrically connects to the first flexible circuit board 22 via the first conductive lead 32 of the edge-bonding region 124. As such, the touch panel 15 may connect to the mainboard 60 via the first circuit board 22. The first flexible circuit board 22 may connect to the second flexible circuit board 24 without the connector, and the overall thickness of the display device may not be increased. There is no overlapping portion between the first flexible circuit board 22 and the second flexible circuit board 24, and the bending of the first flexible circuit board 22 may not be affected by the second flexible circuit board 24 and the components, such as the connectors, which may facilitate to the internal configuration and the small-sized design of the display device, and may improve user experience.

In one example, the display device may further include a thin film packaging layer 18 and a substrate layer 19. The thin film packaging layer 18 is configured between the touch panel 15 and the light-emitting layer 14, and is configured to protect the light-emitting layer 14. Specifically, the thin film packaging layer 18 is bonded to the touch panel 15 via the OCA 16. The substrate layer 19 is configured on one side of the array substrate 12 facing away the light-emitting layer 14. In one example, the substrate layer 19 may be a polyimide (PI) layer.

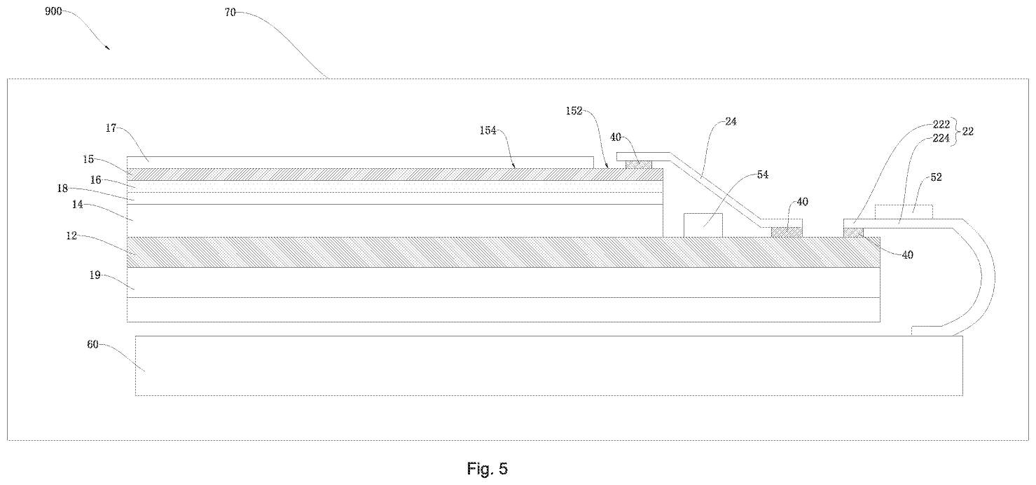

Referring to FIG. 5, the present disclosure relates to a display device 900, including the mainboard 60 and the display panel 700 as described above. The display panel 700 electrically connects to the mainboard 60 via the first flexible circuit board 22. In one example, the display device 900 may include a casing 70 configured to accommodate the display panel 700, with a display surface of the display panel 700 facing outward, and the mainboard 60. The casing 70 is configured to protect the display panel 700 and the mainboard 60.

The second flexible circuit board 24 electrically connects to the first flexible circuit board 22 via the first conductive lead 32 of the edge-bonding region 124. As such, the touch panel 15 may connect to the mainboard 60 via the first circuit board 22. The first flexible circuit board 22 may connect to the second flexible circuit board 24 without the connector, and the thickness of the display device 900 may not be increased. There is no overlapping portion between the first flexible circuit board 22 and the second flexible circuit board 24, and the bending of the first flexible circuit board 22 may not be affected by the second flexible circuit board 24 and the components, such as the connectors, which may facilitate to the internal configuration and the small-sized design of the display device 900, and may improve user experience.

Above are embodiments of the present invention, which does not limit the scope of the present invention. Any equivalent amendments within the spirit and principles of the embodiment described above should be covered by the protected scope of the invention.

What is claimed is:

1. A display panel, comprising:
an array substrate, a light-emitting layer, a touch panel; a first flexible circuit board; and a second flexible circuit board;
wherein the array substrate comprises a display region and an edge-bonding region configured on an edge of the display region, the light-emitting layer is stacked on the display region, and the first flexible circuit board joins to the edge-bonding region;
the touch panel is stacked on one side of the light-emitting layer facing away the array substrate, the second flexible circuit board is flexibly connected between the touch panel and the edge-bonding region, and the edge-bonding region comprises a first conductive lead, and the second flexible circuit board connects to the first flexible circuit board via the first conductive lead.

2. The display panel according to claim 1; wherein the display panel further comprises a touch chip disposed on the first flexible circuit board, and the touch chip electrically connects to the touch panel via the first flexible circuit board and the second flexible circuit board.

3. The display panel according to claim 2, wherein the first flexible circuit board comprises a fixing end and a carrying portion integrally connected with each other, the fixing end joins to the edge-bonding region, the carrying portion is configured outside of the array substrate; and the carrying portion is configured to carry the touch chip.

4. The display panel according to claim 3, wherein the display panel further comprises a display driving chip configured on the edge-bonding region, and a vertical projection of the second flexible circuit board with respect to the array substrate covers the display driving chip.

5. The display panel according to claim 4, wherein a bonding region of the second flexible circuit board is formed between a connecting portion of the second flexible circuit board and the edge-bonding area, and a connecting portion between the display driving chip and the edge-bonding region, and the bonding region of the second flexible circuit board are interleaved with each other.

6. The display panel according to claim 5, wherein the display panel further comprises a cover stacked on one side of the touch panel facing away the light-emitting layer;
a touch area is formed on a vertical projection area of the cover with respect to the touch panel, one side of the touch area is configured with an edge region, and the second flexible circuit board joins to the edge region.

7. The display panel according to claim 4, wherein the edge-bonding region further comprises a second conductive lead, the display driving chip electrically connect to the first flexible circuit board via the second conductive lead, and the first conductive lead and the second conductive lead are interleaved with each other.

8. The display panel according to claim 1, wherein the display panel further comprises an optical clear adhesive (OCA) layer, and the touch panel is fixed on the light-emitting layer via the OCA layer.

9. The display panel according to claim 8, wherein the first flexible circuit board and the second flexible circuit board are bonded on the edge-bonding region via an anisotropic conductive film (ACF).

10. A display device comprising a mainboard and a display panel, wherein the display panel comprises:
an array substrate, a light-emitting layer, a touch panel, a first flexible circuit board, and a second flexible circuit board;
wherein the array substrate comprises a display region and an edge-bonding region configured on an edge of the display region, the light-emitting layer is stacked on the display region, and the first flexible circuit board joins to the edge-bonding region;
the touch panel is stacked on one side of the array substrate facing away the light-emitting layer, the second flexible circuit board is flexibly connected between the touch panel and the edge-bonding region, and the edge-bonding region comprises a first conductive lead, and the second flexible circuit board connects to the first flexible circuit board via the first conductive lead;
the display panel electrically connects to the mainboard via the first flexible circuit board.

11. The display device according to claim 10, wherein the display panel further comprises a touch chip disposed on the first flexible circuit board, and the touch chip electrically connects to the touch panel via the first flexible circuit board and the second flexible circuit board.

12. The display device according to claim 11, wherein the first flexible circuit board comprises a fixing end and a carrying portion integrally connected with each other, the fixing end joins to the edge-bonding region, the carrying portion is configured outside of the array substrate, and the carrying portion is configured to carry the touch chip.

13. The display device according to claim 12, wherein the display panel further comprises a display driving chip configured on the edge-bonding region, and a vertical projection of the second flexible circuit board with respect to the array substrate covers the display driving chip.

14. The display device according to claim 13, wherein a bonding region of the second flexible circuit board is formed between a connecting portion of the second flexible circuit board and the edge-bonding area, and a connecting portion between the display driving chip and the edge-bonding region, and the bonding region of the second flexible circuit board are interleaved with each other.

15. The display device according to claim 14, wherein the display panel further comprises a cover stacked on one side of the touch panel facing away the light-emitting layer;
a touch area is formed on a vertical projection area of the cover with respect to the touch panel, one side of the touch area is configured with an edge region, and the second flexible circuit board joins to the edge region.

16. The display device according to claim 13, wherein the edge-bonding region further comprises a second conductive lead, the display driving chip electrically connect to the first flexible circuit board via the second conductive lead, and the first conductive lead and the second conductive lead are interleaved with each other.

17. The display device according to claim 10, wherein the display panel further comprises an OCA layer, and the touch panel is fixed on the light-emitting layer via the OCA layer.

18. The display device according to claim 17, wherein the first flexible circuit board and the second flexible circuit board are bonded on the edge-bonding region via an ACF.
